(19) United States
(12) Patent Application Publication
(10) Pub. No.: US 2026/0182415 A1
(43) Pub. Date: Jun. 25, 2026

(54) SEMICONDUCTOR DEVICES AND METHODS OF MANUFACTURE

(71) Applicant: Taiwan Semiconductor Manufacturing Co., Ltd., Hsinchu (TW)

(72) Inventors: Chien-He Wang, Hsinchu (TW); Jung-Hau Shiu, New Taipei City (TW); Hsiao-Kuan Wei, Longtan Township (TW)

(21) Appl. No.: 19/001,290

(22) Filed: Dec. 24, 2024

(51) Int. Cl. H01L 23/498; H01L 21/02; H01L 21/768

(52) U.S. Cl. CPC H10W 70/65; H10P 14/69433; H10W 20/023; H10W 20/075; H10W 20/086; H10W 70/685; H10W 20/056; H10W 20/062

(57) ABSTRACT

Semiconductor devices and methods of manufacture are presented which includes: forming metallization layers over a semiconductor substrate; forming a first redistribution layer over the metallization layers; depositing an etch stop layer over the first redistribution layer, the forming the etch stop layer including: forming a first silicon rich region; and forming a first nitrogen rich region; and forming a first bond pad via through the etch stop layer.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size (e.g., shrinking the semiconductor process node towards the sub-20 nm node), which allows more components to be integrated into a given area. As the demand for miniaturization, higher speed and greater bandwidth, as well as lower power consumption and latency has grown recently, there has grown a need for smaller and more creative packaging techniques of semiconductor dies.

As semiconductor technologies further advance, stacked semiconductor devices, e.g., 3D integrated circuits (3DIC), have emerged as effective to further reduce the physical size of a semiconductor device. In a stacked semiconductor device, active circuits such as logic, memory, processor circuits and the like are fabricated on different semiconductor wafers. Two or more semiconductor wafers may be installed on top of one another to further reduce the form factor of the semiconductor device. However, further improvements in these devices and how they are connected together are desired in order to further reduce the size and improve the operating characteristics of the devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a deposition of layers for a first redistribution layer, in accordance with some embodiments.

FIG. 2 illustrates a deposition of a first portion of a first etch stop layer, in accordance with some embodiments.

FIG. 3 illustrates a deposition of a third portion of the first etch stop layer, in accordance with some embodiments.

FIG. 4 illustrates a deposition of a bulk portion of the first etch stop layer, in accordance with some embodiments.

FIG. 5 illustrates deposition of a plurality of passivation layers, in accordance with some embodiments.

FIG. 6 illustrates formation of a first opening, in accordance with some embodiments.

FIG. 7 illustrates formation of a second opening, in accordance with some embodiments.

FIG. 8 illustrates a liner removal process, in accordance with some embodiments.

FIG. 9 illustrates a deposition of conductive material, in accordance with some embodiments.

FIG. 10 illustrates a planarization process, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be described herein with respect to specific embodiments in which an etch stop layer with a variable composition is formed adjacent to redistribution layers, allowing for a reduced possibility for delamination in an N2 process node. The embodiments presented, however, are not intended to be limited to the precise embodiments described below, as the embodiments and ideas may be implemented in any suitable device or structure. For example, the embodiments may be implemented in other etch stop layers formed over conductive materials. All such embodiments are fully intended to be included within the scope of the disclosure.

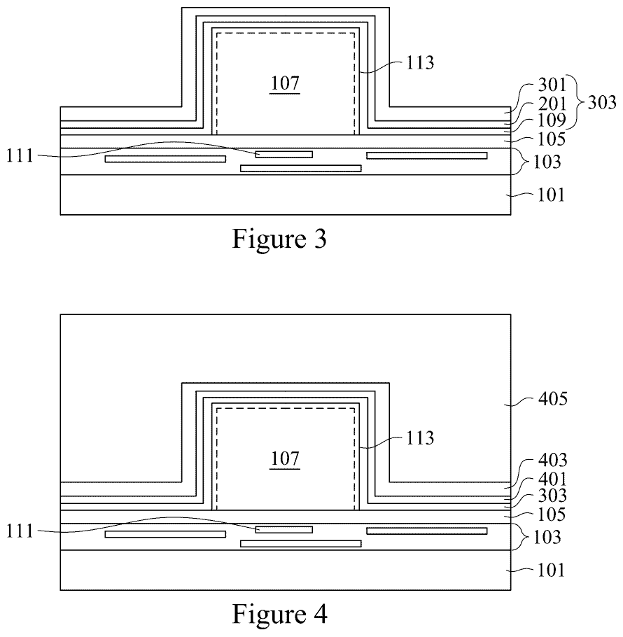

With reference now to FIG. 1, there is illustrated a semiconductor substrate 101, metallization layers 103, a first barrier layer 105, a first RDL 107, and a first portion 109 of a first etch stop layer 303 (not seen in FIG. 1 but seen in completed form below in FIG. 3) over the semiconductor substrate 101. In an embodiment the semiconductor substrate 101 may comprise bulk silicon, doped or undoped, or an active layer of a silicon-on-insulator (SOI) substrate. Generally, an SOI substrate comprises a layer of a semiconductor material such as silicon, germanium, silicon germanium, SOI, silicon germanium on insulator (SGOI), or combinations thereof. Other substrates that may be used include multi-layered substrates, gradient substrates, or hybrid orientation substrates.

Active devices (not separately visible in FIG. 1) may be formed on the semiconductor substrate 101. In an embodiment the active devices may comprise a wide variety of active devices such as transistors (planar, finFET, multi-channel, nanostructure, combinations of these, or the like) and the like and passive devices such as capacitors, resistors, inductors and the like that may be used to generate the desired structural and functional parts of the design. The active devices and passive devices may be formed using any suitable methods either within or else on the semiconductor substrate 101.

The metallization layers 103 are formed over the semiconductor substrate 101 and the active devices and are designed to connect the various active devices to form functional circuitry for the design. In an embodiment the metallization layers 103 are formed of layers of dielectric and conductive material and may be formed through any suitable process (such as deposition, damascene, dual damascene, etc.). In an embodiment there may be a first interlayer dielectric layer (ILD), a first metallization layer with a second ILD and contacts embedded within the second ILD, and a third ILD over the second ILD.

In an embodiment the conductive material may be a material such as copper formed using, e.g., a damascene or dual damascene process, whereby an opening is formed within the dielectric material of the metallization layers 103, the opening is filled and/or overfilled with a conductive material such as copper, and a planarization process is performed to embed the conductive material within the dielectric material. However, any suitable material and any suitable process may be used to form the metallization layers 103.

As part of the metallization layers 103, a top metal layer 111 is formed as a top most layer within the metallization layers 103. In an embodiment the top metal layer 111 includes a dielectric layer and conductive features formed within the dielectric layer. The top metal layer 111 may be formed by initially depositing the dielectric layer over a top surface of underlying layers of the metallization layers 103. The dielectric layer may be deposited by chemical vapor deposition (CVD), physical vapor deposition (PVD), or the like. However, any suitable material and method of deposition may be utilized.

Once the dielectric layer has been formed, the dielectric layer may then be etched to form openings exposing a top surface of the underlying layers (not separately illustrated) of the metallization layers 103. In an embodiment the dielectric layer may be etched using, e.g., a via first dual damascene process, whereby a first masking and etching process is utilized to pattern and etch a via pattern at least partially into the dielectric layer. Once the via pattern is etched, a second masking and etching process is utilized to pattern and etch a trench pattern into the dielectric layer, wherein the etching of the trench pattern further extends the via pattern through the dielectric layer to expose the underlying layer.

However, while a via first dual damascene structure is described, this is intended to merely be illustrative and is not intended to be limiting upon the embodiments. Rather, any suitable process or processes may be utilized to form the via openings and trench openings of the top metal layer 111. For example, a trench first dual damascene process, or even multiple single damascene processes, may be utilized. All such processes are fully intended to be included within the scope of the embodiments.

Once the via openings and trench openings have been formed, the conductive features may be formed by depositing conductive material in the via openings and the trench openings using, for example, a plating process. In an embodiment the conductive features may include conductive trenches and conductive vias connecting the conductive trenches to underlying structures. In an embodiment the conductive material may be copper, a copper alloy, aluminum, an aluminum alloy, combinations of these, or the like. However, any suitable material and any suitable process of formation may be utilized.

Once the via openings and trench openings have been filled and/or overfilled by the conductive material, the conductive features may be formed by removing excess material from outside of the via openings and the trench openings. In an embodiment the removal may be performed using a planarization process such as a chemical mechanical polishing (CMP) process. However, any suitable removal process may be utilized.

In another embodiment, instead of using a damascene or dual damascene process to form the conductive features embedded within the dielectric layer, the conductive features may comprise a material such as an aluminum copper alloy. In such an embodiment the conductive features within the top metal layer 111 may be formed by first blanket depositing the material (e.g., aluminum copper) using a deposition process such as physical vapor deposition, chemical vapor deposition, combinations of these, or the like. Once the material has been deposited, the material may be pattered into the desired shape using, e.g., a photolithographic masking and etching process.

Further, once the conductive features have been formed into the desired shape, the dielectric layer may be deposited over the conductive features. In an embodiment the dielectric layer may be deposited as described above in order to cover the conductive features. Once covered, the dielectric layer may be planarized using, e.g., a chemical mechanical polishing process, in order to provide a planar surface for subsequent processing.

Optionally, if desired, once the top metal layer 111 has been formed, the conductive material within the top metal layer 111 may be covered by yet another dielectric layer. In an embodiment the dielectric layer placed over the top metal layer 111 may be deposited using any suitable process such as CVD, ALD, PVD, spin-on, combinations of these, or the like, and may be any suitable material as described above.

FIG. 1 additionally illustrates formation of the first barrier layer 105 overlying the metallization layers 103 (and in electrical connection with at least a portion of the metallization layers 103). In an embodiment the first barrier layer 105 may be a barrier material such as by being a metallic material such as TiN, Ta, Ti, TiAlN, TaC, TaCN, TaSiN, Mn, Zr, TaN, Ru, Mo, WN, other metal oxides, metal nitrides, metal silicates, transition metal-oxides, transition metal-nitrides, transition metal-silicates, oxynitride of metals, metal aluminates, zirconium silicate, zirconium aluminate, combinations of these (e.g., a combination of tantalum nitride and tantalum), or the like. In a particular embodiment the first barrier layer 105 comprises a first layer of titanium nitride and a second layer of tantalum. Additionally, the first barrier layer 105 may be deposited using a deposition process such as atomic layer deposition, chemical vapor deposition, sputtering, or the like, to a thickness of between about 5 Å and about 200 Å, although any suitable deposition process or thickness may be used.

The first redistribution layer (RDL) 107 is formed over the first barrier layer 105. In an embodiment the first RDL 107 is formed of a conductive material such as an aluminum copper alloy (wherein the aluminum copper alloy may have any suitable weight-% of copper doping in the aluminum matrix), although other suitable materials, such as aluminum, copper, tungsten, composite layers of different materials, or the like, may be utilized. The material of the first RDL 107 may be formed using a process such as plating, whereby a seed layer is deposited, a photoresist is placed and patterned into the desired shape for the first RDL 107, the first RDL107 is plated onto the seed layer, the photoresist is removed, and the seed layer is etched to form the first RDL 107 in the desired pattern. However, any suitable material, process, and thickness may be utilized.

In an embodiment the first RDL 107 may have a thickness of about 28,000 Å and a width of about 3.2 μm. Additionally, the first RDL 107 may be spaced apart from a second RDL (not separately illustrated in FIG. 1) by an oxide spacing. In a particular embodiment the oxide spacing may be greater than about 2.4 μm, such as about 3 μm, 6 μm, and 10μm. However, any suitable oxide spacing may be utilized.

Once the first RDL 107 has been formed, the first etch stop layer 303 is begun to be formed over the first RDL 107 with a deposition of the first portion 109 of the first etch stop layer 303. The first portion 109 may be a material such as silicon nitride, silicon oxynitride, silicon carbon-nitride combinations of these, or the like, formed using a deposition process such as plasma enhanced chemical vapor deposition (PECVD), plasma enhanced atomic layer deposition (PEALD), combinations of these, or the like, to a thickness of between about 30 Å and about 100 Å, such as about 50 Å. However, any suitable material, deposition process, and thickness may be utilized.

Additionally, in an embodiment the first portion 109 of the first etch stop layer 303 may be a material that is rich in a bonding element to help improve the bonding between the first etch stop layer 303 and the material of the underlying first RDL 107 (e.g., copper). For example, in an embodiment in which the first etch stop layer 303 comprises silicon nitride and the first RDL 107 comprises copper, the first bonding element may be silicon and the first portion 109 may be formed to be silicon rich. For example, in particular embodiments the first portion 109 of the first etch stop layer 303 may have a nitrogen to silicon ratio of less than about 0.9, such as about 0.75. However, any suitable ratio may be utilized.

In order to obtain the silicon-rich material, the PECVD process may utilize a first precursor material such as silane (which will be converted into a plasma) and a second precursor material such as ammonia (NH₃) or nitrogen (N₂) (which will also be converted into a plasma). In an embodiment the first precursor material may be flowed at a flow rate of between about 50 sccm and about 200 sccm, while the second precursor material may be flowed at a flow rate of between about 10,000 sccm and about 20,000 sccm. Additionally, the deposition process may be performed at a power of less than about 300 watts, and the first portion 109 may be formed to a thickness of between about 50 Å and about 100 Å. However, any suitable precursors and parameters may be utilized.

Additionally, because the first portion 109 of the first etch stop layer 303 is rich in the bonding element such as silicon, the bonding element may diffuse into the material of the first RDL 107 to form an intermixed region 113. For example, in an embodiment in which the first RDL 107 is copper and the first portion 109 is silicon-rich silicon nitride, the silicon will diffuse into the first RDL 107 to form a CuSi material. Additionally, the nitrogen will not significantly diffuse, and remains below detection limits within the intermixed region 113. In an embodiment the intermixed region 113 has a thickness of about 500 Å. However, any suitable thickness may be utilized.

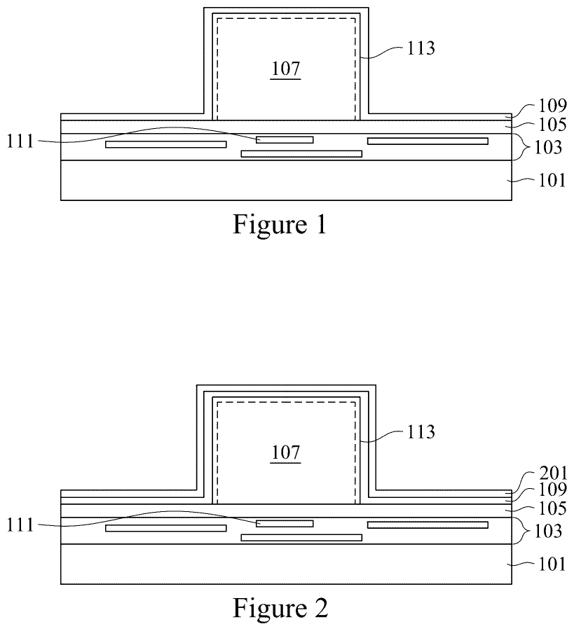

FIG. 2 illustrates a second portion 201 of the first etch stop layer 303 is formed over the first portion 109 of the first etch stop layer 303. In an embodiment the second portion 201 is a similar material as the first portion 109 (e.g., silicon nitride), but which has a different composition to bridge the differences between the first portion 109 and an overlying bulk portion 301 of the first etch stop layer 303 (not illustrated in FIG. 2 but illustrated and described further below with respect to FIG. 3). In a particular embodiment in which the second portion 201 is silicon nitride, the second portion 201 may have a nitrogen to silicon ratio that is larger than the first portion 109, such as being greater than 0.9, such as 1.21. However, any suitable ratio may be utilized.

In order to obtain the nitrogen-rich material, the PECVD process may utilize the first precursor material and the second precursor material in either the same deposition chamber or a different deposition chamber. In some embodiments the first precursor material and the second precursor material may be held at the same flow rates as during the deposition of the first portion 109. Additionally, however, the deposition process may be performed at a higher power than during the deposition of the first portion 109, such as a power of greater than about 300 watts, such as 560 watts. As such, the second portion 201 may be formed to a thickness of between about 15 Å and about 100 Å, such as about 60 Å. However, any suitable precursors and parameters may be utilized.

FIG. 3 illustrates a bulk portion 301 of the first etch stop layer 303 is formed over the second portion 201 of the first etch stop layer 303. In an embodiment the bulk portion 301 is a similar material as the first portion 109 and the second portion 201 (e.g., silicon nitride), but which has a different composition. For example, the bulk portion 301 may be formed using the same precursors as the first portion 109 and the second portion 201, but with different parameters, in either the same deposition chamber or a different deposition chamber. In a particular embodiment in which the bulk portion 301 is silicon nitride, the bulk portion 301 may have a nitrogen to silicon ratio that is between the first portion 109 and the second portion 201, such as being about 1.1. Once the bulk portion 301 has been formed, the first etch stop layer 203 may have a thickness of about 1,500 Å. However, any suitable ratio may be utilized.

FIG. 4 illustrates that, once the first etch stop layer 303 (illustrated in FIG. 4 in a simplified format) has been formed, a first passivation layer 401 is formed. In an embodiment the first passivation layer 401 may be a dielectric material such as silicon nitride, silicon oxide, silicon oxynitride, silicon carbide, silicon oxycarbide, combinations of different layers of these, or the like, using a deposition process such as chemical vapor deposition, physical vapor deposition, atomic layer deposition, combinations of these, or the like to a thickness of about 1,000 Å. However, any suitable materials and methods of deposition may be utilized.

Once the first passivation layer 401 has been formed, a second passivation layer 403 (e.g., a liner) may be formed over the first passivation layer 401. In an embodiment the second passivation layer 403 may be another dielectric material different from the first passivation layer 401, such as silicon oxide, silicon nitride, silicon oxynitride, silicon carbide, combinations of these, or the like, using a deposition process such as chemical vapor deposition, physical vapor deposition, atomic layer deposition, combinations of these, or the like to a thickness of about 1,000 Å. However, any suitable materials and methods of deposition may be utilized.

A third passivation layer 405 is formed over the second passivation layer 403. In an embodiment the third passivation layer 405 may be another dielectric material different from the first passivation layer 401 and the second passivation layer 403, such as a high-density plasma (HDP) oxide, or the like, using a deposition process such as chemical vapor deposition, physical vapor deposition, atomic layer deposition, combinations of these, or the like. However, any suitable materials and methods of deposition may be utilized.

Additionally, once the third passivation layer 405 has been deposited, the third passivation layer 405 is planarized in order to provide a planar surface for subsequent depositions. In an embodiment the planarization process may be a process such as a chemical mechanical polishing process, a grinding process, one or more etch back processes, combinations of these, or the like to a final thickness of about 7,000 Å. However, any suitable planarization process may be utilized.

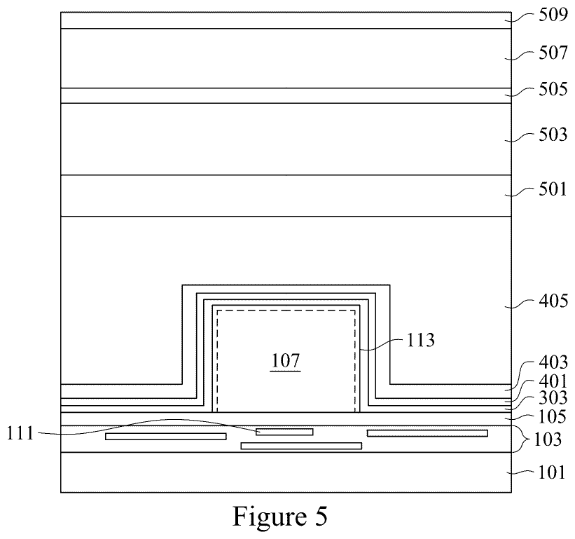

FIG. 5 illustrates deposition of a second etch stop layer 501 over the third passivation layer 405. In an embodiment the second etch stop layer 501 may be a dielectric material such as silicon nitride, silicon oxynitride, silicon carbide, silicon oxycarbide, combinations of these, or the like, using a deposition process such as chemical vapor deposition, physical vapor deposition, atomic layer deposition, combinations of these, or the like to a thickness of about 7,000 Å. However, any suitable materials and methods of deposition may be utilized.

FIG. 5 also illustrates deposition of a fourth passivation layer 503 over the second etch stop layer 501. In an embodiment the fourth passivation layer 503 may be another dielectric material different from the second etch stop layer 501, such as silicon oxide (e.g., TEOS), silicon nitride, silicon oxynitride, silicon carbide, combinations of these, or the like, using a deposition process such as chemical vapor deposition, physical vapor deposition, atomic layer deposition, combinations of these, or the like to a thickness of about 10,000 Å. However, any suitable materials and methods of deposition may be utilized.

A third etch stop layer 505 is formed over the fourth passivation layer 503. In an embodiment the third etch stop layer 505 may be a dielectric material such as silicon nitride, silicon oxynitride, silicon carbide, silicon oxycarbide, combinations of these, or the like, using a deposition process such as chemical vapor deposition, physical vapor deposition, atomic layer deposition, combinations of these, or the like, to a thickness of about 750 Å. However, any suitable materials and methods of deposition may be utilized.

A fifth passivation layer 507 is formed over the third etch stop layer 505. In an embodiment the fifth passivation layer 507 may be another dielectric material different from the third etch stop layer 505, such as silicon oxide (e.g., TEOS), silicon nitride, silicon oxynitride, silicon carbide, combinations of these, or the like, using a deposition process such as chemical vapor deposition, physical vapor deposition, atomic layer deposition, combinations of these, or the like, to a thickness of about 6,000 Å. However, any suitable materials and methods of deposition may be utilized.

A sixth passivation layer 509 is formed over the fifth passivation layer 507. In an embodiment the sixth passivation layer 509 may be another dielectric material different from the fifth passivation layer 507, such as USG, silicon oxide, silicon nitride, silicon oxynitride, silicon carbide, combinations of these, or the like, using a deposition process such as chemical vapor deposition, physical vapor deposition, atomic layer deposition, combinations of these, or the like, to a thickness of about 3,000 Å. However, any suitable materials and methods of deposition may be utilized.

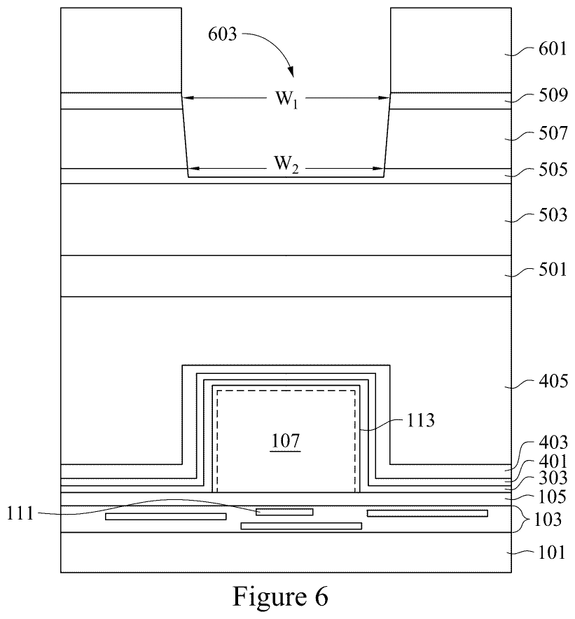

FIG. 6 illustrates placement and patterning of a first photoresist 601 in order to initiate formation of a first opening 603. In an embodiment the first photoresist 601 may be a single layer of photosensitive material or a multi-layer photoresist. In an embodiment the first photoresist 601 may be placed, imaged, and developed in order to pattern the first photoresist 601.

Once the first photoresist 601 has been formed, the first photoresist 601 is used in a formation of the first opening 603 using the first photoresist 601 as a mask. In an embodiment the first opening 603 may be formed using one or more etching processes along with the first photoresist 601 to remove portions of the sixth passivation layer 509 and the fifth passivation layer 507 before stopping on or partially through the third etch stop layer 505. However, any suitable etching processes may be utilized.

In an embodiment the first opening 603 may be formed to have a first width W₁ at a top of the sixth passivation layer 509 of between about 1.5 μm and about 3.0 μm. Additionally, the first opening 603 may be formed to have a second width W₂ at a bottom of the fifth passivation layer 507 of between about 1.5 μm and about 3.0 μm. However, any suitable widths may be utilized.

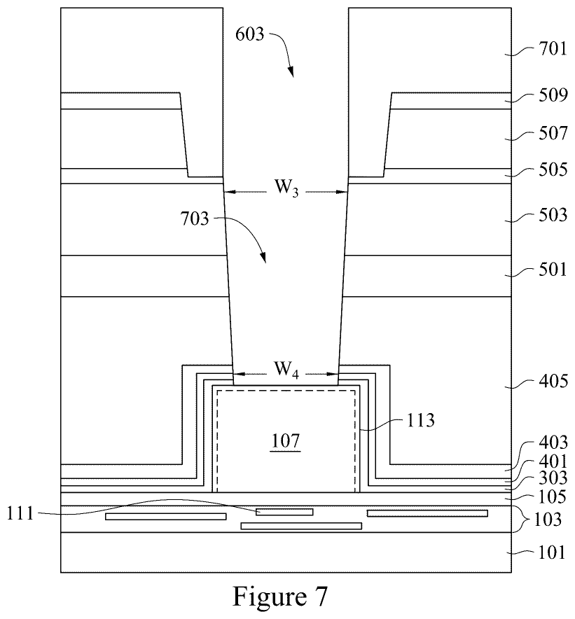

FIG. 7 illustrates placement and patterning of a second photoresist 701 in order to initiate formation of a second opening 703. In an embodiment the second photoresist 701 may be similar to the first photoresist 601 (described above with respect to FIG. 6), such as by being a single layer of photosensitive material or a multi-layer photoresist. In an embodiment the second photoresist 701 may be placed, imaged, and developed in order to pattern the second photoresist 701.

Once the second photoresist 701 has been formed, the second photoresist 701 is used in a formation of the second opening 703 (which may otherwise be seen as an extension of the first opening 603) through the second third etch stop layer 505, the fourth passivation layer 503, the second etch stop layer 501, and the third passivation layer 405. In an embodiment one or more etching processes may be used to etch through the third etch stop layer 505 and the fourth passivation layer 503. Once the third etch stop layer 505 and the fourth passivation layer 503 have been etched, a flush may be used. However, any suitable etchants and processes may be utilized.

Once the second opening 703 has been formed through the fourth passivation layer 503, the second opening 703 may be extended through the second etch stop layer 501, the third passivation layer 405, the second passivation layer 403, and the first passivation layer 401 and stopping on or partially through the first etch stop layer 303. In an embodiment one or more etching processes may be used to etch through the second etch stop layer 501, the third passivation layer 405, the second passivation layer 403, and the first passivation layer 401. However, any suitable etchants and processes may be utilized.

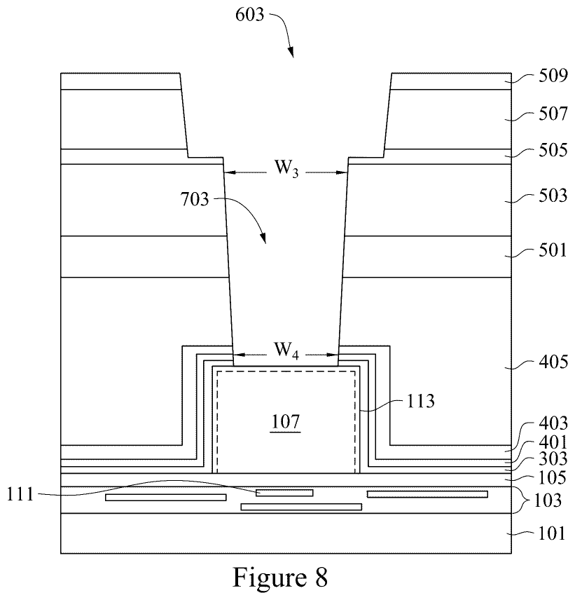

FIG. 8 illustrates that, once the second etch stop layer 501, the third passivation layer 405, the second passivation layer 403, and the first passivation layer 401 have been etched, the second photoresist 701 may be removed. In an embodiment the second photoresist 701 may be removed using an ashing process, whereby a temperature of the second photoresist 701 is increased in an ambient environment of reactants such as oxygen and CₓO_{y}. However, any suitable process and/or reactants may be utilized to remove the second photoresist 701.

Additionally, once the second photoresist 701 has been removed, a liner removal process (LRM) may be utilized to etch through the first etch stop layer 303 to expose the underlying first RDL 107. In an embodiment the liner removal process may be a low-rf power, dry etching process using etchants selective to the materials of the first etch stop layer 303. As such, in an embodiment in which the first etch stop layer 303 is silicon nitride, the liner removal process may use an etchant such as CₓF_{y} to extend the second opening 703 through the first etch stop layer 303. However, any suitable processes may be utilized.

In an embodiment the second opening 703 may be formed to have a third width W₃ at a top of the fourth passivation layer 503 of between about 1.0 μm and about 2.5 μm. Additionally, the second opening 703 may be formed to have a fourth width W₄ at a bottom of the first etch stop layer 303 of between about 1.0 μm and about 2.5 μm. However, any suitable widths may be utilized.

Optionally, once the first RDL 107 has been exposed, the second opening 703 may be extended at least partially, if not fully, into and/or through the first RDL 107. In an embodiment the second opening 703 may be extended using one or more etching processes, such as a sputtering process. For example, in one embodiment a sputter etch utilizing a precursor such as argon may be utilized in order to remove portions of the first RDL 107. However, any suitable process may be utilized.

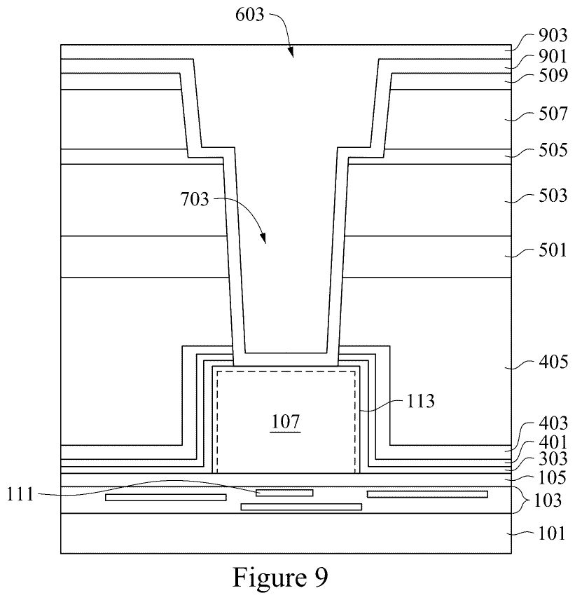

FIG. 9 illustrates deposition of a second barrier layer 901 and a conductive material 903 within the first opening 603 and the second opening 703. In an embodiment the second barrier layer 901 may be similar to the first barrier layer 105, such as by being a metallic material such as TiN, Ti, TiAlN, TaC, TaCN, TaSiN, Mn, Zr, TaN, Ru, Mo, WN, other metal oxides, metal nitrides, metal silicates, transition metal-oxides, transition metal-nitrides, transition metal-silicates, oxynitride of metals, metal aluminates, zirconium silicate, zirconium aluminate, combinations of these (e.g., a combination of tantalum nitride and tantalum), or the like. Additionally, the second barrier layer 901 may be deposited using a deposition process such as atomic layer deposition, chemical vapor deposition, sputtering, or the like, to a thickness of between about 5 Å and about 200 Å, although any suitable deposition process or thickness may be used.

To initiate formation of the conductive material 903, a first seed layer (not separately illustrated) is deposited adjacent to the second barrier layer 901. In an embodiment the first seed layer is a thin layer of a conductive material that aids in the formation of a thicker layer during subsequent processing steps. The first seed layer may comprise a layer of titanium about 1,000 Å thick followed by a layer of copper about 5,000 Å thick. The first seed layer may be created using processes such as sputtering, evaporation, or PECVD processes, depending upon the desired materials. The first seed layer may be formed to have a thickness of between about 0.3 μm and about 1 μm, such as about 0.5 μm.

Once the first seed layer has been deposited, the conductive material 903 is deposited to fill and/or overfill the first opening 603 and the second opening 703. In an embodiment the conductive material 903 comprises one or more conductive materials, such as copper, tungsten, other conductive metals, or the like, and may be formed, for example, by electroplating, electroless plating, or the like. In an embodiment, an electroplating process is used wherein the first seed layer is submerged or immersed in an electroplating solution. The first seed layer surface is electrically connected to the negative side of an external DC power supply such that the first seed layer functions as the cathode in the electroplating process. A solid conductive anode, such as a copper anode, is also immersed in the solution and is attached to the positive side of the power supply. The atoms from the anode are dissolved into the solution, from which the cathode, e.g., the first seed layer, acquires the dissolved atoms, thereby plating the exposed conductive areas of the first seed layer.

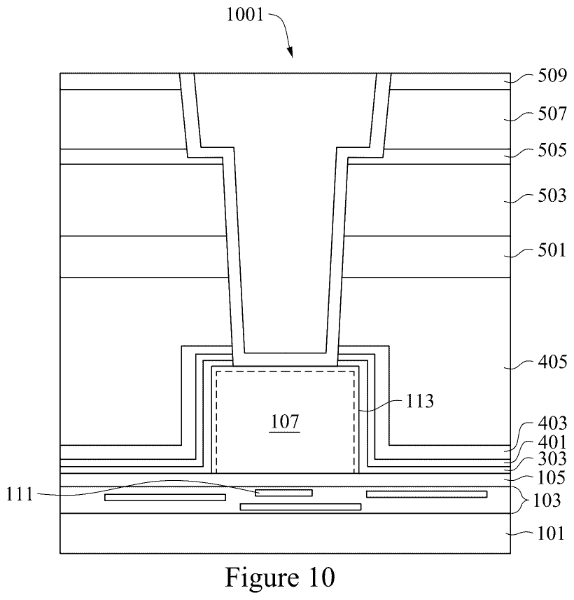

FIG. 10 illustrates a planarization process that is used to planarize the second barrier layer 901 and the conductive material 903 in order to form a first bond pad via 1001. In an embodiment the planarization process may be a process such as a chemical mechanical polishing process, a grinding process, one or more etch back processes, combinations of these, or the like. However, any suitable planarization process may be utilized.

By utilizing the embodiments presented herein, a tunable amount of silicon-copper bonding and silicon diffusion depth profile can be achieved which can help to improve adhesion to the underlying material (e.g., copper). In some embodiments the adhesion may be improved by +10% (using a nano-scratch measurement). By improving the adhesion, dielectric to metal delamination may be reduced, and the oxide spacing rule can be improved from no more than 2.4 μm to a more customer friendly 6 μm. For example, at oxide spacings of about 3 μm and about 6 μm, there is no delamination from stress mismatch, and only a 10% delamination at an oxide spacing of about 10 μm.

In accordance with an embodiment, a method of manufacturing a semiconductor device includes: forming metallization layers over a semiconductor substrate; forming a first redistribution layer over the metallization layers; depositing an etch stop layer over the first redistribution layer, the forming the etch stop layer including: forming a first silicon rich region; and forming a first nitrogen rich region; and forming a first bond pad via through the etch stop layer. In an embodiment the etch stop layer comprises silicon nitride. In an embodiment the first silicon rich region has a nitrogen to silicon ratio of less than about 0.9. In an embodiment the first silicon rich region has a nitrogen to silicon ratio of about 0.75. In an embodiment the first nitrogen rich region has a nitrogen to silicon ratio of greater than about 0.9. In an embodiment the first nitrogen rich region has a nitrogen to silicon ratio of about 1.21. In an embodiment the forming the first silicon rich region further forms a copper-silicon region within the first redistribution layer.

In accordance with another embodiment, a method of manufacturing a semiconductor device includes: depositing a first portion of a first etch stop layer in physical contact with a conductive portion of a first redistribution layer, the first portion having a first nitrogen to silicon ratio; depositing a second portion of the first etch stop layer, the second portion having a second nitrogen to silicon ratio greater than the first nitrogen to silicon ratio; depositing a bulk portion of the first etch stop layer, the bulk portion having a third nitrogen to silicon ratio between the first nitrogen to silicon ratio and the second nitrogen to silicon ratio; and forming a first bond pad via through the first etch stop layer. In an embodiment the first nitrogen to silicon ratio is less than 0.9. In an embodiment the second nitrogen to silicon ratio is greater than 0.9. In an embodiment the forming the first portion is performed with first flow rates of first precursors and wherein the forming the second portion is performed with the first flow rates of the first precursors. In an embodiment the forming the first portion is performed with a first power and the forming the second portion is performed with a second power different from the first power. In an embodiment the second power is larger than the first power. In an embodiment the first etch stop layer comprises silicon nitride.

In accordance with yet another embodiment, a semiconductor device includes: metallization layers over a semiconductor substrate; a first etch stop layer in physical contact with a conductive portion of the metallization layers, the first etch stop layer including: a first silicon rich region; a first nitrogen rich region over the first silicon rich region; and a first bulk region over the first nitrogen rich region; and a first bond pad via extending through the first etch stop layer. In an embodiment the first etch stop layer comprises silicon nitride. In an embodiment the first silicon rich region has a nitrogen to silicon ratio of less than about 0.9. In an embodiment the first silicon rich region has a nitrogen to silicon ratio of about 0.75. In an embodiment the first nitrogen rich region has a nitrogen to silicon ratio of greater than about 0.9. In an embodiment the first nitrogen rich region has a nitrogen to silicon ratio of about 1.21.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, the method comprising:
forming metallization layers over a semiconductor substrate;
forming a first redistribution layer over the metallization layers;
depositing an etch stop layer over the first redistribution layer, the forming the etch stop layer comprising:
forming a first silicon rich region; and
forming a first nitrogen rich region; and
forming a first bond pad via through the etch stop layer.

2. The method of claim 1, wherein the etch stop layer comprises silicon nitride.

3. The method of claim 1, wherein the first silicon rich region has a nitrogen to silicon ratio of less than about 0.9.

4. The method of claim 3, wherein the first silicon rich region has a nitrogen to silicon ratio of about 0.75.

5. The method of claim 1, wherein the first nitrogen rich region has a nitrogen to silicon ratio of greater than about 0.9.

6. The method of claim 5, wherein the first nitrogen rich region has a nitrogen to silicon ratio of about 1.21.

7. The method of claim 1, wherein the forming the first silicon rich region further forms a copper-silicon region within the first redistribution layer.

8. A method of manufacturing a semiconductor device, the method comprising:
depositing a first portion of a first etch stop layer in physical contact with a conductive portion of a first redistribution layer, the first portion having a first nitrogen to silicon ratio;
depositing a second portion of the first etch stop layer, the second portion having a second nitrogen to silicon ratio greater than the first nitrogen to silicon ratio;
depositing a bulk portion of the first etch stop layer, the bulk portion having a third nitrogen to silicon ratio between the first nitrogen to silicon ratio and the second nitrogen to silicon ratio; and
forming a first bond pad via through the first etch stop layer.

9. The method of claim 8, wherein the first nitrogen to silicon ratio is less than 0.9.

10. The method of claim 9, wherein the second nitrogen to silicon ratio is greater than 0.9.

11. The method of claim 8, wherein the forming the first portion is performed with first flow rates of first precursors and wherein the forming the second portion is performed with the first flow rates of the first precursors.

12. The method of claim 11, wherein the forming the first portion is performed with a first power and the forming the second portion is performed with a second power different from the first power.

13. The method of claim 12, wherein the second power is larger than the first power.

14. The method of claim 8, wherein the first etch stop layer comprises silicon nitride.

15. A semiconductor device comprising:
metallization layers over a semiconductor substrate;
a first etch stop layer in physical contact with a conductive portion of the metallization layers, the first etch stop layer comprising:
a first silicon rich region;
a first nitrogen rich region over the first silicon rich region; and
a first bulk region over the first nitrogen rich region; and
a first bond pad via extending through the first etch stop layer.

16. The semiconductor device of claim 15, wherein the first etch stop layer comprises silicon nitride.

17. The semiconductor device of claim 15, wherein the first silicon rich region has a nitrogen to silicon ratio of less than about 0.9.

18. The semiconductor device of claim 17, wherein the first silicon rich region has a nitrogen to silicon ratio of about 0.75.

19. The semiconductor device of claim 15, wherein the first nitrogen rich region has a nitrogen to silicon ratio of greater than about 0.9.

20. The semiconductor device of claim 19, wherein the first nitrogen rich region has a nitrogen to silicon ratio of about 1.21.
